(19) United States
(12) Patent Application Publication
(10) Pub. No.: US 2008/0318389 A1
(43) Pub. Date: Dec. 25, 2008

(54) METHOD OF FORMING ALIGNMENT KEY OF SEMICONDUCTOR DEVICE

(76) Inventor: Myung-Soo Kim, Gangnam-gu (KR)

Correspondence Address: SHERR & VAUGHN, PLLC, 620 HERNDON PARKWAY, SUITE 200, HERNDON, VA, 20170, US

(21) Appl. No.: 12/137,669

(22) Filed: Jun. 12, 2008

(30) Foreign Application Priority Data
Jun. 25, 2007 (KR) 10-2007-0062077

(51) Int. Cl. H01L 21/76

(52) U.S. Cl. 438/401; 257/E21.54

(57) ABSTRACT

The formation of an alignment key for overlay measurement of a semiconductor device formed by sequentially forming an inter-metal dielectric layer and a capping layer over a semiconductor substrate, and patterning the inter-metal dielectric layer and a capping layer at an alignment key region to thereby form an alignment key hole. A metal layer may then be deposited over the semiconductor substrate including alignment key hole and then an uppermost surface of the deposited metal layer may then be polished to thereby form the alignment key having a step. Accordingly, a dishing phenomenon occurring at the time of polishing using a capping layer can be prevented and an alignment key having a desired step can be formed.

The present application claims priority under 35 U.S.C. §119 to Korean Patent Application No. 10-2007-0062077 (filed Jun. 25, 2007), which is hereby incorporated by reference in its entirety.

### BACKGROUND

An alignment key of a semiconductor device is a pattern formed generally to check whether a previously-formed first pattern and subsequently-formed second pattern are accurately formed at a specific location and to also correctly align a mask pattern at a specific location on and/or over a wafer. The alignment key is formed generally on and/or over a scribe line that separates a wafer into a plurality of dies. Meaning, the number of alignment keys can be as many as the number of masks which are necessary to pattern a thin film formed on and/or over a semiconductor substrate, and can also be formed on and/or over the scribe line on every thin film layer.

The requirement to achieve high integration of semiconductor devices has resulted in the use of multi-line devices. In order to implement such a multi-line device, polishing of insulating material between metal lines and metal material is indispensably required. The multi-line device can be implemented by repeatedly performing a chemical mechanical polishing (CMP) process after the insulating material and the metal material are deposited.

Example FIGS. 1A to 1D illustrate a method of fabricating a semiconductor device that can include forming inter-metal dielectric layer 102 composed of an oxide film on and/or over semiconductor substrate 100. Photoresist patterns 104 can then be formed on and/or over inter-metal dielectric layer 102. Inter-metal dielectric layer 102 can be formed simultaneously when an inter-metal dielectric layer between lower and upper metal lines is formed. Photoresist patterns 104 can be formed simultaneously when the photoresist patterns for forming contact holes are formed.

As illustrated in example FIG. 1B, inter-metal dielectric layer 102 can be etched along photoresist patterns 104 to form hole A for forming an alignment key in a region in which the alignment key on a scribe line of semiconductor substrate 100 will be formed. Photoresist patterns 104 can then be removed through a series of ashing processes. Hole A for forming the alignment key can be formed simultaneously when a contact hole for forming a contact plug is formed.

As illustrated in example FIG. 1C, metal layer 106 can then be thinly deposited on and/or over the entire surface of semiconductor substrate 100 including hole A for forming the alignment key. Metal layer 106 can be formed by depositing a metal material such as tungsten (W) through a physical vapor deposition (PVD) process, etc. Metal layer 106 can be deposited simultaneously when the contact hole is gap-filled with a metal material.

As illustrated in example FIG. 1D, a polishing process employing CMP can then be performed on and/or over an uppermost surface of semiconductor substrate 100 on and/or over which metal layer is formed to thereby form alignment key 106a having a step. The process of forming alignment key 106a can be performed when polishing a top surface of the metal material gap-filled into the contact hole. Such an alignment key formed to measure the overlay of a semiconductor device must be formed with a minimum depth and step so that the alignment key can be detected in a photolithography process. However, if the alignment key is formed in the metal line formation process illustrated in FIGS. 1A to 1D, a dishing phenomenon occurs in the alignment key formation region according to the etch selectivity of the inter-metal dielectric layer and the metal material after the polishing process, resulting in a lowered step. This makes it difficult to detect an alignment key signal value for overlay measurement of a specific pattern. Accordingly, a problem occurred in checking whether an accurate pattern was formed.

### SUMMARY

Embodiments relate to a method of forming an alignment key of a semiconductor device in which overlay measurement can be easily performed by employing an alignment key by forming the alignment key having a desired step, even after a capping layer is deposited on and/or over an inter-metal dielectric layer and then polished.

Embodiments relate to a method that may include at least one of the following steps: sequentially depositing an inter-metal dielectric layer and a capping layer on and/or over a semiconductor substrate; and then forming a hole for forming the alignment key by pattering the inter-metal dielectric layer and the capping layer in an alignment key formation region of the semiconductor substrate; and then depositing a metal layer on and/or over the semiconductor substrate including the hole for forming the alignment key; and then forming the alignment key by polishing the uppermost surface of the semiconductor substrate on which the metal layer is deposited to expose the capping layer.

Embodiments relate to a method that may include at least one of the following steps: forming an inter-metal dielectric layer on a scribe line of a semiconductor substrate; and then forming a capping layer on the inter-metal dielectric layer; and then performing a pattering process on the inter-metal dielectric layer and the capping layer to form an alignment key hole; and then forming a metal layer on the capping layer and in the alignment key hole; and then performing a first polishing process on portion of the uppermost surface of the metal layer formed on the capping layer to expose the capping layer and thereby form an alignment key in the alignment key hole; and then performing a second polishing process on the exposed capping layer and an exposed uppermost surface of the alignment key.

Embodiments relate to an apparatus that may include at least one of the following: an inter-metal dielectric layer formed on a scribe line of a semiconductor substrate; a capping layer formed on the inter-metal dielectric layer; an alignment key hole formed in the inter-metal dielectric layer and the capping layer.

### DRAWINGS

Example FIGS. 1A to 1D illustrate a method of fabricating a semiconductor device.

Example FIGS. 2A to 2D illustrate a method of forming an alignment key in accordance with embodiments.

Example FIG. 3 is a graph illustrating the amount of erosion after performing a polishing process in accordance with embodiments.

FIG. 4 is a diagram illustrating optical images of an alignment key made in accordance with the thickness of a formed capping layer at the time of overlay measurement after a polishing process, in accordance with embodiments.

Example FIG. 5 is a diagram illustrating detection signals of an alignment key in a lithography process after the alignment key is formed in accordance with embodiments.

Example FIG. 6 is a graph illustrating the 3-sigma value of an overlay in accordance with the thickness of a capping layer in accordance with embodiments.

Example FIG. 7 is a graph illustrating the reduction of 3-sigma values of an overlay in accordance with the thickness of a capping layer while a plurality of lot-to-lot processes is performed, in accordance with embodiments.

### DESCRIPTION

In accordance with embodiments, an inter-metal dielectric layer and a capping layer may be deposited on and/or over a scribe line of a semiconductor substrate. The inter-metal dielectric layer and the capping layer may be patterned to form a hole for forming an alignment key. A thin metal layer may then be deposited on and/or over the semiconductor substrate including the hole for forming the alignment key. An uppermost surface of the metal layer may then be polished to thereby form the alignment key having a step.

As illustrated in example FIG. 2A, inter-metal dielectric layer 202 and capping layer 204 may be sequentially deposited on and/or over semiconductor substrate 200 using a PVD process such as sputtering. Inter-metal dielectric layer 202 and capping layer 204 may be formed simultaneously when an inter-metal dielectric layer between lower and upper metal lines and a capping layer are formed. Inter-metal dielectric layer 202 may be deposited to a thickness of between approximately 4500 to 5500 angstrom using an oxide film, such as at least one of tetra ethyl ortho silicate (TEOS), boron phosphorus silicate glass (BPSG), undoped silicate glass (USG) and fluorine-doped silicate glass (FSG). Capping layer 204 may be deposited to a thickness of between approximately 2000 to 2500 angstrom using a silicon film such as SiH₄.

As illustrated in example FIG. 2B, inter-metal dielectric layer 202 and capping layer 204 may then be etched along a specific photoresist pattern to thereby form hole B for forming an alignment key in an alignment key region on and/or over a scribe line of semiconductor substrate 200. The photoresist pattern may then be removed through a series of ashing processes. Hole B for forming the alignment key can be formed simultaneously when forming a contact hole for forming a contact plug.

As illustrated in example FIG. 2C, metal layer 206 may then be thinly deposited on and/or over the entire surface of semiconductor substrate 200 including hole B for forming the alignment key. Metal layer 206 may be composed of an opaque material and deposited using tungsten (W) or copper (Cu). Metal layer 206 may be formed through a PVD process such as a sputtering method. Metal layer 206 may be deposited simultaneously when the contact hole is gap-filled with a second metal layer.

As illustrated in example FIG. 2D, an uppermost surface of semiconductor substrate 200 on and/or over which metal layer 206 is deposited is subject to a polishing process employing CMP, thereby forming alignment key 206a having a step. The polishing process can be performed simultaneously with the polishing of the uppermost surface of the gap-filled contact hole. The polishing process may include processes of polishing metal layer 206 exposing capping layer 204 and then polishing uppermost surfaces of the exposed capping layer 204 and alignment key 206a sing a touch-up slurry. Accordingly, alignment key 206a having a desired step can be formed by depositing inter-metal dielectric layer 202 and capping layer 204 on and/or over the scribe line of semiconductor substrate 200, and then forming a hole for forming alignment key 206a, and then depositing metal layer 206 in hole B and over capping layer 204, and then performing a polishing process on the uppermost surface of semiconductor substrate 200 on and/or over which metal layer 206 is formed.

As illustrated in example FIG. 3, the amount of erosion is shown with respect to an alignment key when a metal layer is subject to a polishing process performed after steps of forming an inter-metal dielectric layer, a capping layer, a hole for forming the alignment key, and a metal layer in the hole. Also shown is the amount of erosion with respect to an alignment key when a polishing process is performed on the metal layer and an exposed capping layer using a touch-up slurry. It can be seen that, as the thickness of a capping layer composed of SiH₄ increases, the amount of erosion decreases. It can also be seen that when the capping layer has a thickness of 2000 angstrom or more, the amount of erosion is saturated.

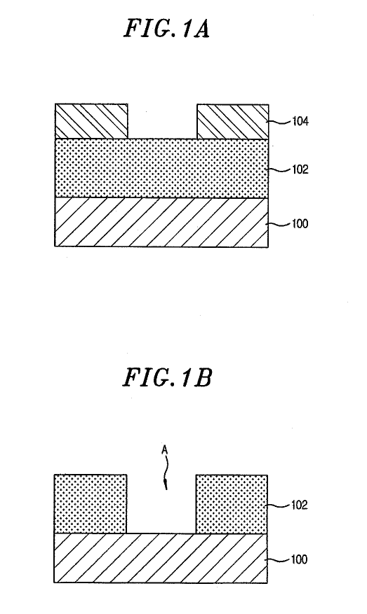

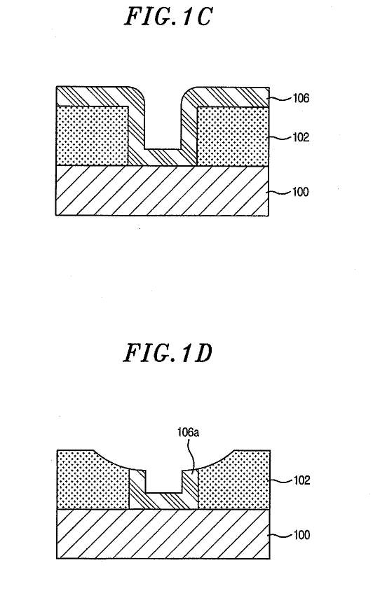

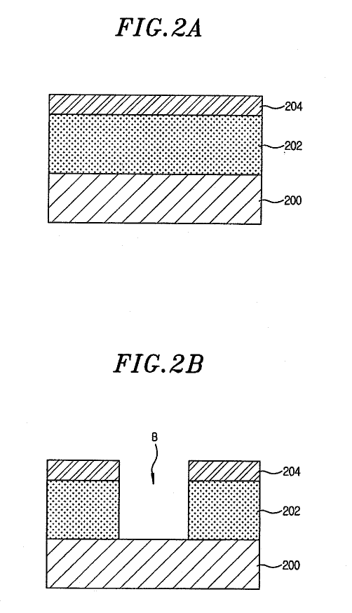

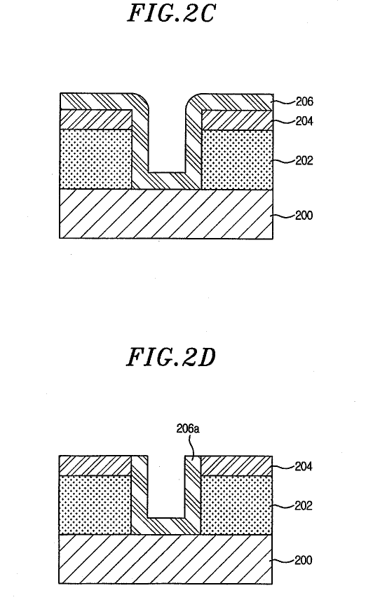

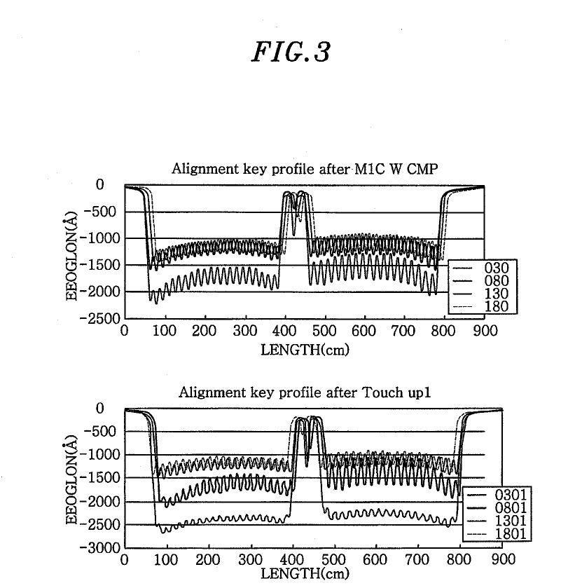

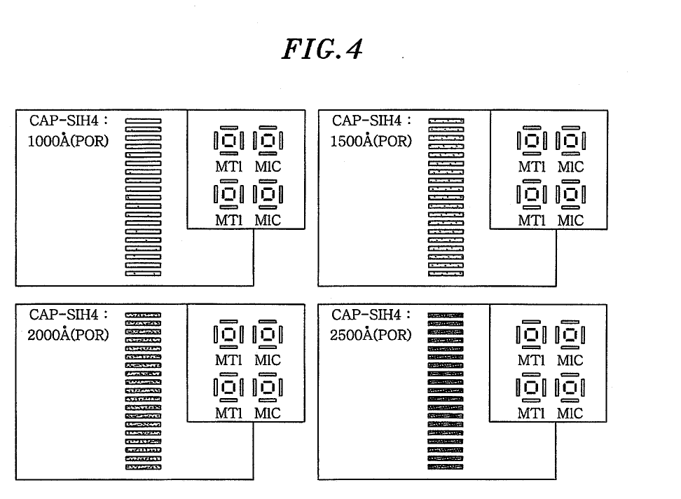

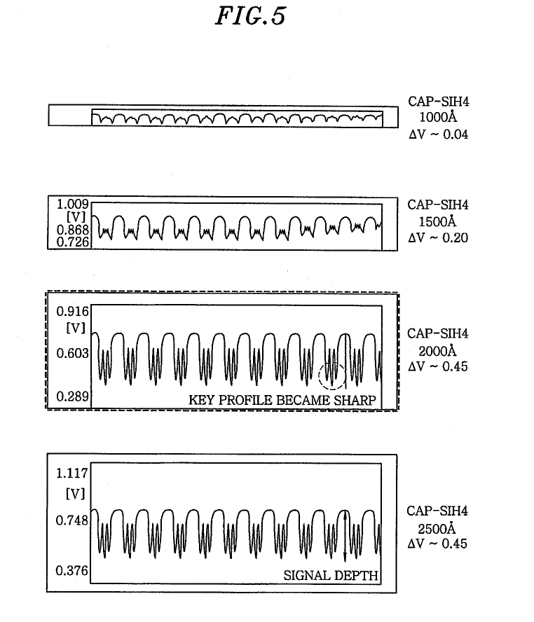

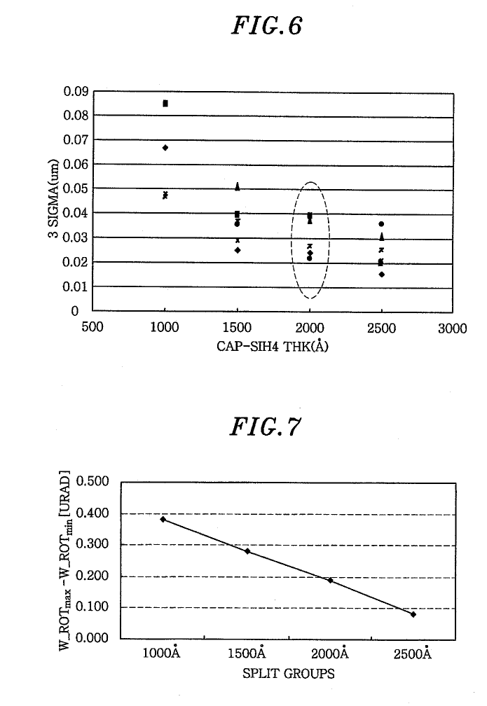

As illustrated in example FIG. 4, as the thickness of the capping layer increases, a discolor problem may be solved. It can also be seen that when the capping layer has a thickness of 1000 or 1500 angstrom, the optical image of the alignment key may exhibit a discoloration problem (i.e., a dishing phenomenon occurring near an overlay box). However, when the capping layer has a thickness of 2000 or 2500 angstrom, the optical image of the alignment key does not have a discoloration problem.

As illustrated in example FIG. 5, a process of detecting an alignment key may include a detecting the location of an alignment key through an image captured by a CCD using a light source having a broadband (for example, 530 nm to 800 nm) emitted from a halogen lamp. The amount of the light source incident on the CCD is represented by voltage, and the alignment key is detected based on the voltage value having minimum and maximum A values. Waveforms and voltage values with respect to detection signals when the thickness of the capping layer composed of SiH₄ is 1000 angstrom, 1500 angstrom, 2000 angstrom, and 2500 angstrom can be seen. It can be seen that as the thickness of the capping layer composed of SiH₄ increases sequentially to 1000 angstrom, 1500 angstrom, 2000 angstrom, and 2500 angstrom, the profile of the detection signal becomes sharp and detection of the detection signal improves significantly, from when the detection signal (the voltage value ΔV) with respect to the alignment key is 2000 angstrom. Using an apparatus for measuring the detection signal of the alignment key, when the depth of the detection signal was set to a voltage value of 0.1V or more when the thickness of the capping layer is 1000 angstrom, the depth of the detection signal (the voltage value ΔV) was measured approximately at 0.04 V. When the thickness of the capping layer is 1500 angstrom, the depth of the detection signal (the voltage value ΔV) was measured approximately at 0.20 V. When the thickness of the capping layer is 2000 angstrom, the depth of the detection signal (the voltage value ΔV) was measured at approximately 0.45 V. When the thickness of the capping layer is 2500 angstrom, the depth of the detection signal (the voltage value ΔV) was measured at approximately 0.46 V. The profiles of the detection signals with respect to these alignment key patterns (in this case, three patterns) are clearly recognized. Meaning, when the thickness of the capping layer is 2000 angstrom or more, the profile of a detection signal with respect to an alignment key becomes sharp, enabling more accurate overlay measurement.

As illustrated in example FIG. 6, when the thickness of the capping layer composed of SiH₄ is 1000 angstrom, 1500 angstrom, 2000 angstrom, and 2500 angstrom, 3-sigma (σ) values (that is, 3×standard deviation values) with respect to the accuracy and reappearance of an overlay can be seen. Four points appearing when the thickness of the capping layer composed of SiH₄ is 1000 angstrom refer to a semiconductor wafer on which the process cannot be further performed since alignment error occurred in one semiconductor wafer. It can be seen that when the thickness of the capping layer composed of SiH₄ is 2000 angstrom or 2500 angstrom, deviation of an overlay converges into a range of 20 nm to 40 nm. Accordingly, in a polishing process, the capping layer reduces the dishing phenomenon occurring in the inter-metal dielectric layer, so that an alignment key having a step is formed accurately. Consequently, the profile of an alignment key pattern can be improved, and an accurate overlay can be measured.

As illustrated in example FIG. 7, the 3-sigma values of an overlay is reduced according to the thickness of a capping layer while a plurality of lot-to-lot processes is performed in accordance with embodiments. It can be seen that not only deviation of overlay data with respect to each lot, but also the range of minimum and maximum values of the overlay, which were measured per on a lot-to-lot basis, was reduced to 20 nm or less from when the thickness of the capping layer is 2000 angstrom. It can also be seen that as the thickness of the capping layer increases, minimum and maximum values of semiconductor wafers per on a lot-to-lot basis were reduced at a linear proportion ratio.

In accordance with embodiments, an inter-metal dielectric layer and a capping layer may be sequentially deposited on and/or over a semiconductor substrate, and then the inter-metal dielectric layer and the capping layer are patterned in an alignment key region to thereby form a hole for forming the alignment key, and the a metal layer is deposited on and/or over the semiconductor substrate including the hole for forming the alignment key, and then an uppermost surface of the deposited metal layer is polished to thereby form the alignment key having a step. This is unlike a method requiring patterning only the inter-metal dielectric layer to form a hole for forming an alignment key, and then depositing a metal layer on the semiconductor substrate including the hole, and then performing a polishing process on the deposited metal layer to form an alignment key having a step. Accordingly, a dishing phenomenon occurring at the time of polishing using a capping layer can be prevented and an alignment key having a desired step can be formed. Moreover, a discoloration problem of an alignment key pattern, which occurs when an overlay is measured, can be prevented using the alignment key having a desired step, and a detection signal of the alignment key can be detected more clearly. Consequently, overlay measurement can be performed easily and the yield of semiconductor devices can be improved.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
sequentially forming an inter-metal dielectric layer and a capping layer over a semiconductor substrate; and then
forming an alignment key hole by pattering the inter-metal dielectric layer and the capping layer at an alignment key region of the semiconductor substrate; and then
forming a metal layer over the semiconductor substrate and in the alignment key hole; and then
forming an alignment key by performing a polishing process on the uppermost surface of the metal layer to expose the capping layer.

2. The method of claim 1, wherein sequentially forming the inter-metal dielectric layer and the capping layer comprises:
sequentially depositing as the inter-metal dielectric layer an oxide film on the semiconductor substrate and as the capping layer a silicon film on the inter-metal dielectric layer.

3. The method of claim 2, wherein the oxide film comprises at least one of tetra ethyl ortho silicate, boron phosphorus silicate glass, undoped silicate glass and fluorine-doped silicate glass.

4. The method of claim 3, wherein the inter-metal dielectric layer is deposited to a thickness of between approximately 4500 angstrom to 5500 angstrom.

5. The method of claim 2, wherein the silicon film comprises SiH₄.

6. The method of claim 5, wherein the capping layer is deposited to a thickness of between approximately 2000 angstrom to 2500 angstrom.

7. The method of claim 1, wherein depositing the metal layer comprises:
depositing at least one of tungsten and copper over the semiconductor substrate and in the alignment key hole.

8. The method of claim 1, further comprising, after forming the alignment key, performing a second polishing process on the exposed portion of the capping layer and an uppermost surface of the alignment key.

9. The method of claim 8, wherein the second polishing process is performed using a touch-up slurry.

10. An apparatus comprising:
an inter-metal dielectric layer formed on a scribe line of a semiconductor substrate;
a capping layer formed on the inter-metal dielectric layer;
an alignment key hole formed in the inter-metal dielectric layer and the capping layer.

11. The apparatus of claim 10, wherein the alignment key is composed of a metal layer.

12. The apparatus of claim 11, wherein the metal layer comprises at least one of tungsten and copper.

13. The apparatus of claim 10, wherein the inter-metal dielectric layer comprises an oxide film.

14. The method of claim 3, wherein the oxide film is formed at a thickness of between approximately 4500 angstrom to 5500 angstrom.

15. The apparatus of claim 14, wherein the oxide film comprises at least one of tetra ethyl ortho silicate, boron phosphorus silicate glass, undoped silicate glass and fluorine-doped silicate glass.

16. The apparatus of claim 10, wherein the capping layer comprises a silicon film.

17. The apparatus of claim 16, wherein the silicon film is formed at a thickness of between approximately 2000 angstrom to 2500 angstrom.

18. The apparatus of claim 17, wherein the silicon film comprises SiH₄.

19. A method comprising:
forming an inter-metal dielectric layer on a scribe line of a semiconductor substrate; and then
forming a capping layer on the inter-metal dielectric layer; and then
performing a pattering process on the inter-metal dielectric layer and the capping layer to form an alignment key hole; and then
forming a metal layer on the capping layer and in the alignment key hole; and then
performing a first polishing process on portion of the uppermost surface of the metal layer formed on the capping layer to expose the capping layer and thereby form an alignment key in the alignment key hole; and then
performing a second polishing process on the exposed capping layer and an exposed uppermost surface of the alignment key.

20. The method of claim 19, wherein the inter-metal dielectric layer comprises at least one of tetra ethyl ortho silicate, boron phosphorus silicate glass, undoped silicate glass and fluorine-doped silicate glass and the capping layer comprises SiH₄.
